(19) United States
(12) Patent Application Publication
(10) Pub. No.: US 2018/0321281 A1
(43) Pub. Date: Nov. 8, 2018

(54) CURRENT SENSOR

(71) Applicant: Yazaki Corporation, Tokyo (JP)

(72) Inventor: Toshiaki FUKUHARA, Shizuoka (JP)

(73) Assignee: Yazaki Corporation, Tokyo (JP)

(21) Appl. No.: 15/960,763

(22) Filed: Apr. 24, 2018

(30) Foreign Application Priority Data
May 8, 2017 (JP) 2017-092341

(51) Int. Cl. G01R 15/20

(52) U.S. Cl. CPC G01R 15/202

(57) ABSTRACT

A current sensor includes: a magnetic core member configured to generate magnetic flux corresponding to current flowing through the conducting member; a magnetic sensor configured to output a signal corresponding to a magnetic flux density of the gap portion of the magnetic core member; a magnetic shield member including a shield main body that surrounds external sides of a core main body of the magnetic core member, the shield main body being operable to shield magnetism between an interior and an exterior of the shield main body; and a sensor housing member internally housing the magnetic core member, the magnetic sensor, and the magnetic shield member.

### CROSS-REFERENCE TO RELATED APPLICATION(S)

The present application claims priority to and incorporates by reference the entire contents of Japanese Patent Application No. 2017-092341 filed in Japan on May 8, 2017.

### BACKGROUND OF THE INVENTION

### 1. Field of the Invention

The present invention relates to a current sensor.

### 2. Description of the Related Art

A current sensor that measures current flowing through a conducting member such as a busbar is conventionally known. Such a current sensor includes: a magnetic core member that internally surrounds a conducting member and generates magnetic flux corresponding to current flowing through this conducting member; and a magnetism detecting element (such as a Hall element) that outputs a signal corresponding to the magnetic flux of this magnetic core member. The magnetic core member and the magnetism detecting element are housed in a housing compartment of a housing member formed of an insulating material such as a synthetic resin, and are retained in the housing compartment together with the conducting member through which current is measured. The current sensor of this type is disclosed in, for example, Japanese Patent Application Laid-open No. 2014-109518.

A conducting member the current through which is measured generates a larger amount of heat when the current flowing therethrough is larger. For this reason, a current sensor desirably tends to be unaffected by heat from a conducting member in consideration of the possibility that the conducting member is raised to a high temperature.

### SUMMARY OF THE INVENTION

The present invention is therefore directed to providing a current sensor having high thermal resistance.

A current sensor according to one aspect of the present invention includes a magnetic core member including a core main body formed of a cylindrical body that internally surrounds, at a distance, a conducting member through which electricity is passed, the cylindrical body having a gap portion formed therein that is formed as a slit extending in a direction along a cylinder axis of the cylindrical body, the magnetic core member being configured to generate magnetic flux corresponding to current flowing through the conducting member; a magnetic sensor configured to output a signal corresponding to a magnetic flux density of the gap portion; a magnetic shield member including a shield main body that surrounds external sides of the core main body, the shield main body being operable to shield magnetism between an interior and an exterior of the shield main body; and a sensor housing member configured to internally house the magnetic core member, the magnetic sensor, and the magnetic shield member, wherein the sensor housing member includes a cylindrical housing body shaped as a cylinder and operable to be inserted through the interior of the magnetic core member in a direction along the cylinder axis and have the conducting member inserted through the interior of the cylindrical housing body itself in the direction along the cylinder axis, the cylindrical housing body includes an internal circumferential wall disposed facing and spaced a gap apart from the conducting member that has been inserted through the cylindrical housing body, the gap being annular, and a plurality of holding portions protruding from a plurality of respective locations of the internal circumferential wall toward the conducting member that has been inserted through the cylindrical housing body, the holding portions being operable to hold the conducting member with the gap being maintained, and the cylindrical housing body forms an air layer using the gap between the cylindrical housing body and the conducting member that has been inserted through the interior thereof.

According to another aspect of the present invention, in the current sensor, it is preferable that each of the holding portions is formed in a manner such that, in a section thereof perpendicular to the cylinder axis, and in a contact point side thereof with the conducting member in the perpendicular section, the cross-section area per unit length in a direction of protrusion of the holding portion decreases toward the contact point with the conducting member.

According to still another aspect of the present invention, in the current sensor, it is preferable that in an alternating-current circuit that includes a plurality of the conducting members, combinations each composed of the magnetic core member, the magnetic sensor, and the magnetic shield member are provided to the respective conducting members, and the individual cylindrical housing body is provided to each of the conducting members in the alternating-current circuit.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a current sensor in an embodiment;

FIG. 2 is a plan view of the current sensor in the embodiment as viewed from a direction along a cylinder axis;

FIG. 3 is an exploded perspective view of the current sensor in the embodiment;

FIG. 4 explains an application example of the current sensor in the embodiment and is a perspective view of a current sensor device for a power control unit (PCU);

FIG. 5 is an exploded perspective view of the current sensor device; and

FIG. 6 is a sectional view taken along the X-X line of FIG. 4.

### DETAILED DESCRIPTION OF THE PREFERRED EMBODIMENTS

The following describes an embodiment of a current sensor according to the present invention in detail based on the drawings. This embodiment is not intended to limit this invention.

### EMBODIMENT

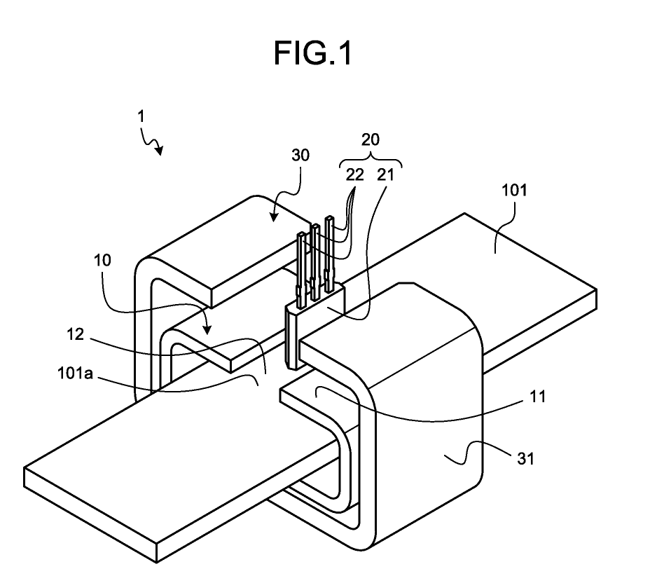

An embodiment of the current sensor according to the present invention is described based on FIG. 1 to FIG. 6.

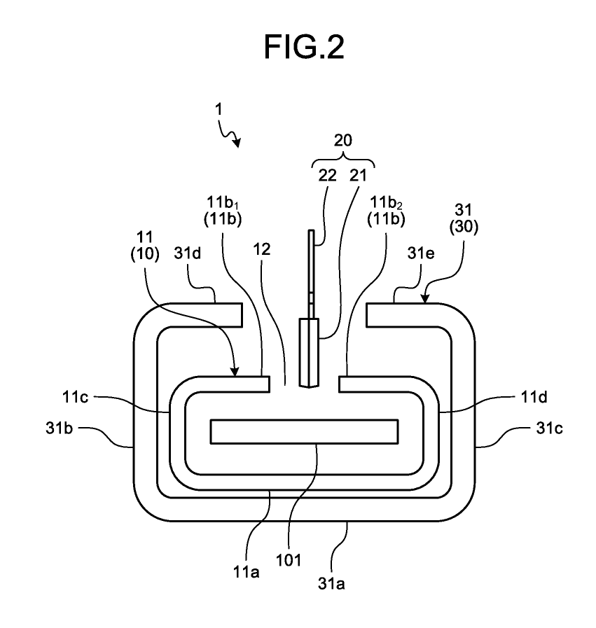

FIG. 1 and FIG. 2 illustrate a current sensor 1 in this embodiment. This current sensor 1 is a sensor that measures current flowing through a conducting member 101 (in FIG. 1 and FIG. 2), which is a member through which electricity is passed. In this embodiment, a busbar formed of a conductive material such as metal and shaped like a plate is presented as the conducting member 101. This current sensor 1 includes a magnetic core member 10, a magnetic sensor 20, and a magnetic shield member 30.

The magnetic core member 10 is a member that generates magnetic flux corresponding to current flowing through the conducting member 101, the member being formed of a magnetic material such as ferrite. This magnetic core member 10 includes a core main body 11. The core main body 11 includes, as a member to form the main shape thereof, a cylindrical body that internally surrounds and is spaced apart from the conducting member 101, the cylindrical body having a gap portion 12 formed therein that is shaped like a slit extending in the direction along the cylinder axis thereof.

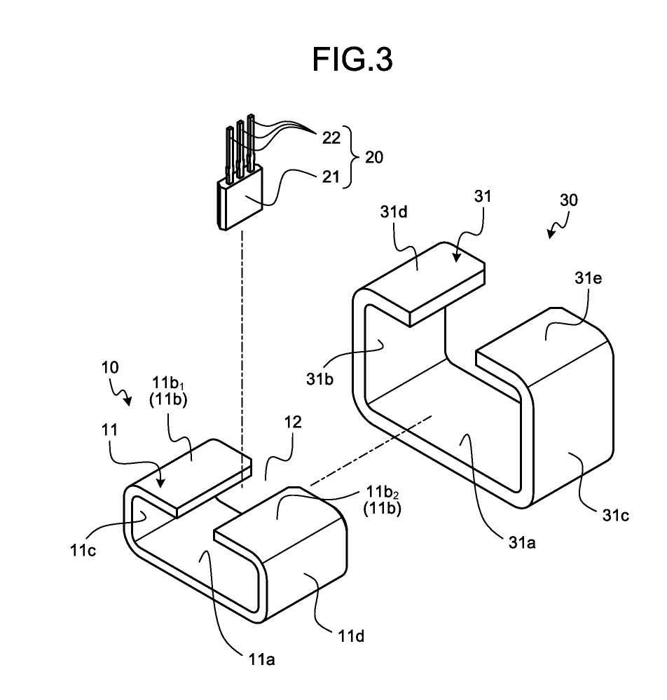

The core main body 11 in this example has the gap portion 12 formed in one of the four walls (first to fourth walls 11a to 11d) constituting the cylindrical body shaped like a rectangular cylinder (FIG. 2 and FIG. 3). This core main body 11 has: the rectangular first wall 11a and the rectangular second wall lib, which are disposed with planar surfaces thereof facing and spaced apart from each other; and the rectangular third wall 11c and the rectangular fourth wall 11d, which are disposed with planar surfaces thereof facing and spaced apart from each other in a direction perpendicular to the direction in which the first wall 11a and the second wall lib face each other. This core main body 11 has the rectangular gap portion 12 formed through the center of the second wall lib. As a result, the second wall lib is divided into two parts facing each other across the gap portion 12, the two parts being a first piece portion 11b₁ abutting the third wall 11c and a second piece portion 11b₂ abutting the fourth wall 11d.

In the magnetic core member 10, the conducting member 101 is inserted through the interior of the core main body 11 in a direction along the cylinder axis, and the conducting member 101 is disposed, in the interior of the core main body 11, facing the gap portion 12. In this embodiment, one of the planar surfaces of the conducting member 101 is disposed facing the gap portion 12. In the conducting member 101, a part disposed facing the gap portion 12 is a portion (hereinafter referred to as “current-measurement subject portion”) 101a the current through which is to be measured (FIG. 1).

The magnetic sensor 20 outputs a signal corresponding to a magnetic flux density of the gap portion 12. This magnetic sensor 20 includes: a main sensor body 21 including a magnetism detecting element; and conductive leads 22 that function to output signals (FIG. 1 to FIG. 3).

In this example, a Hall IC (integrated circuit) is used as the magnetic sensor 20. The Hall IC includes a Hall element serving as a magnetism detecting element, and an amplification circuit that amplifies an output signal from the Hall element, which are not illustrated. The main sensor body 21 has the Hall element and the amplification circuit internally incorporated therein. The Hall element outputs a signal (output signal) of Hall voltage that corresponds to the magnetic flux density. For example, this Hall element is provided at a position a certain distance away from a substantially central portion of the current-measurement subject portion 101a of the conducting member 101 in the width direction thereof in a direction perpendicular to planar surfaces of the conducting member 101. In this embodiment, the main sensor body 21 of the magnetic sensor 20 is disposed in the gap portion 12 so that the Hall element can be thus disposed. In this magnetic sensor 20, the Hall element outputs a signal of Hall voltage corresponding to a magnetic flux density of the gap portion 12, and the output signal is amplified by the amplification circuit. In this magnetic sensor 20, the thus amplified signal is output from the leads 22.

The magnetic shield member 30 includes a shield main body 31 that externally surrounds the core main body 11 of the magnetic core member 10, and the shield main body 31 works to shield magnetism between the interior and the exterior of the shield main body 31. This magnetic shield member 30 is formed of a magnetic material such as ferrite.

The shield main body 31 at least includes a rectangular first wall 31a disposed facing the external side of the first wall 11a of the core main body 11, a rectangular second wall 31b disposed facing the external side of the third wall 11c of the core main body 11, and a rectangular third wall 31c disposed facing the external side of the fourth wall 11d of the core main body 11 (FIG. 2 and FIG. 3). The first wall 31a in this example is formed and disposed so as to be able to screen out the entire first wall 11a from the exterior thereof. The second wall 31b in this example is formed and disposed so as to be able to screen out the entire third wall 11c from the exterior thereof. The third wall 31c in this example is formed and disposed so as to be able to screen out the entire fourth wall 11d from the exterior thereof. In this shield main body 31, the second wall 31b and the third wall 31c are formed perpendicularly from two opposed edge portions of the first wall 31a. In the shield main body 31 composed of these three walls, the magnetic sensor 20 is disposed in a rectangular opening formed between edge portions at respective free ends of the second wall 31b and the third wall 31c. The opening is disposed, at a location external from the core main body 11, facing the gap portion 12 of the magnetic core member 10 while being spaced apart therefrom.

The shield main body 31 in this example further includes a rectangular first piece portion 31d disposed facing the external side of the first piece portion 11b₁ of the core main body 11, and a rectangular second piece portion 31e disposed facing the external side of the second piece portion 11b₂ of the core main body 11 (FIG. 2 and FIG. 3). The first piece portion 31d and the second piece portion 31e are provided to narrow the opening formed by the second wall 31b and the third wall 31c so that an external magnetic field can be prevented from intruding into the interior of the shield main body 31. That is, the interior of the shield main body 31 is more susceptible to an external magnetic field when the opening disposed facing the gap portion 12 is larger. However, the first piece portion 31d and the second piece portion 31e in this example can provide a narrower opening than the opening otherwise formed by the second wall 31b and the third wall 31c, and thus can reduce the influence of the external magnetic field in the interior of the shield main body 31. In consideration of the influence of the external magnetic field, the shield main body 31 in this example has the first piece portion 31d formed from the edge of the second wall 31b in a direction perpendicular thereto toward the third wall 31c (the second piece portion 31e) and has the second piece portion 31e formed from the edge of the third wall 31c in a direction perpendicular thereto toward the second wall 31b (the first piece portion 31d).

This current sensor 1 is provided with respect to each conducting member 101 the current through which is to be measured. For example, an alternating-current (AC) circuit including a plurality of such conducting members 101 may include a plurality of combinations of the magnetic core members 10, the magnetic sensors 20, and the magnetic shield members 30 for the respective conducting members 101.

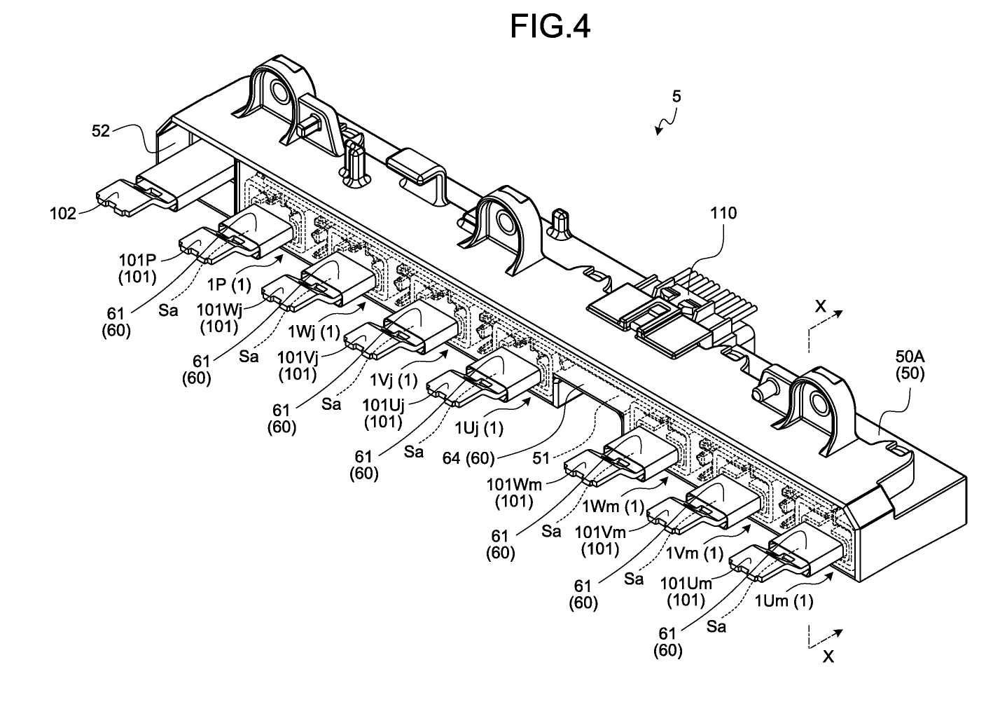

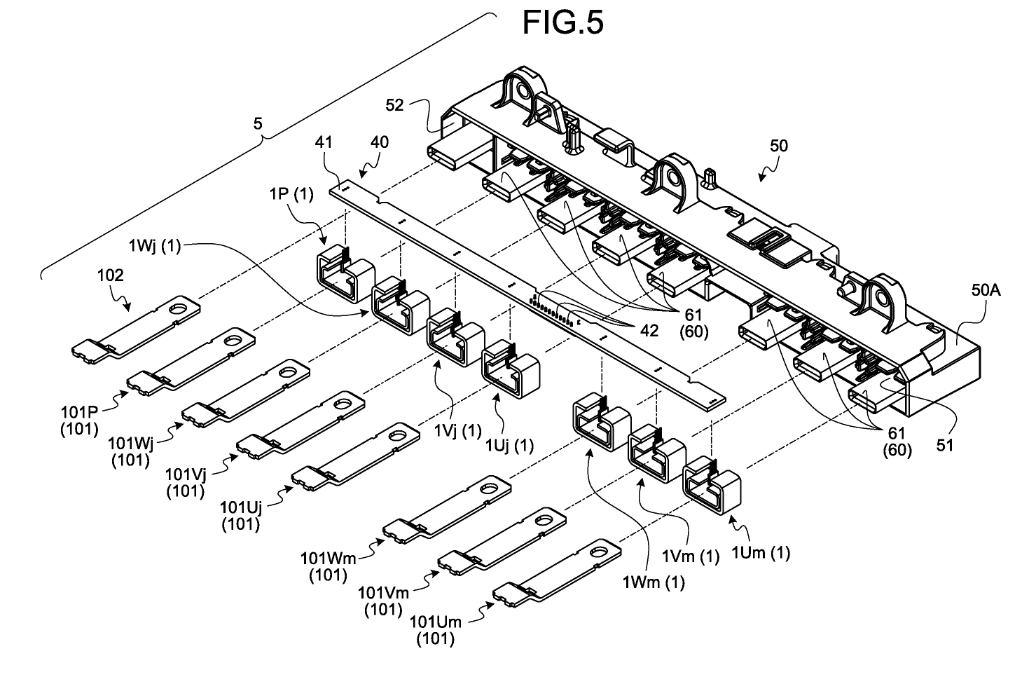

The following describes an application example of this current sensor 1. This example is described as application to a power control unit (PCU) of a vehicle (such as a hybrid vehicle or an electromagnetic vehicle) equipped with a rotating machine (electric motor) as a drive source although the PCU is not illustrated. The PCU includes an inverter (not illustrated) that drives the rotating machine, and a current sensor (hereinafter referred to as a current sensor device for the convenience of explanation) 5 (FIG. 4 and FIG. 5) that measures current through individual phases (the individual conducting members 101) of a three-phase AC circuit. FIG. 5 omits a holding body 64 to be described later.

The current sensor device 5 includes the current sensors 1 for the respective phases. This current sensor device 5 includes, as the current sensors 1, three current sensors 1Um, 1Vm, and 1Wm provided for the U, V, and W phases of a first rotating machine (electric motor), respectively, and three current sensors 1Uj, 1Vj, and 1Wj provided for the U, V, and W phases of a second rotating machine (electric motor), respectively.

The current sensors 1Um, 1Vm, and 1Wm on the part of the first rotating machine measure current flowing through the conducting members 101Um, 101Vm, and 101Wm provided as the conducting members 101 on the part of the first rotating machine. The respective conducting members 101Um, 101Vm, and 101Wm are electrically connected to the U, V, and W phases on the part of the first rotating machine and are also electrically connected to the U, V, and W phases on the part of the inverter. For example, the respective conducting members 101Um, 101Vm, and 101Wm are fixed by, for example, being screwed to respective conducting members (not illustrated) of the U, V, and W phases on the part of the first rotating machine. For example, the respective conducting members 101Um, 101Vm, and 101Wm are fixed by, for example, being welded to respective conducting members (not illustrated) of the U, V, and W phases on the part of the inverter.

The current sensors 1Uj, 1Vj, and 1Wj on the part of the second rotating machine measure current flowing through the current members 101Uj, 101Vj, and 101Wj provided as the conducting members 101 on the part of the second rotating machine. The conducting members 101Uj, 101Vj, and 101Wj are electrically connected to the U, V and W phases on the part of the second rotating machine and are also electrically connected to the U, V, and W phases on the part of the inverter. For example, the respective conducting members 101Uj 101Vj and 101Wj are fixed by, for example, being screwed to respective conducting members (not illustrated) of the U, V, and W phases on the part of the second rotating machine. For example, the respective conducting members 101Uj, 101Vj, and 101Wj are fixed by, for example, being welded to respective conducting members (not illustrated) of the U, V, and W phases on the part of the inverter.

This current sensor device 5 includes, as the current sensor 1, a current sensor 1P provided to the positive side of a controller power supply (not illustrated). The current sensor 1P relates to the conducting member 101 (a conducting member 101P) that is electrically connected to the controller power supply, and measures current flowing through the conducting member 101P.

The current sensor device 5 includes the conducting members 101Um, 101Vm, 101Wm, 101Uj, 101Vj, 101Wj, and 101P together with the respective current sensors 1Um, 1Vm, 1Wm, 1Uj, 1Vj, 1Wj, and 1P. The current sensor device 5 further includes a conducting member 102 that is electrically connected to the negative side of the controller power supply. The respective conducting members 101Um, 101Vm, 101Wm, 101Uj, 101Vj, 101Wj, 101P, and 102 are formed as plate-like busbars. In the current sensor device 5, identical components are used for the respective conducting members 101Um, 101Vm, 101Wm, 101Uj, 101Vj, 101Wj, 101P, and 102.

In this example, the current sensor 1 includes a circuit board 40 to which an output signal from the leads 22 of the magnetic sensor 20 is input (FIG. 5). The circuit board 40 outputs an output signal based on an output signal from the magnetic sensor 20, that is, for example, calculates a current value based on an output signal (signal indicating Hall voltage) from the magnetic sensor 20 and outputs an output signal regarding the current value. For example, the circuit board 40 includes: a rectangular and plate-like main body 41 having an electric circuit formed thereon; and output terminals 42 electrically connected to the electric circuit. The circuit board 40 outputs the generated output signal from the corresponding output terminal 42. A counterpart terminal of a counterpart connector 110 (FIG. 4) is fit to and electrically connected to the output terminal 42. The output signal from the circuit board 40 is transmitted through the counterpart connector to, for example, a signal receiver such as an electronic control device (not illustrated).

The circuit board 40 may be provided to each of the current sensors 1. Only one such circuit board 40 is provided in the current sensor device 5 in this example. The single circuit board 40 is electrically connected to the current sensors 1Um, 1Vm, 1Wm, 1Uj, 1Vj, 1Wj, and 1P. The current sensors 1Um, 1Vm, 1Wm, 1Uj, 1Vj, 1Wj, and 1P are arranged next to each other in the longitudinal direction of the single circuit board 40 and individually electrically connected thereto via the leads 22. The circuit board 40 is disposed external from the shield main body 31 of the magnetic shield member 30 and facing the first piece portions 31d and the second piece portions 31e of the respective current sensors 1Um, 1Vm, 1Wm, 1Uj, 1Vj, 1Wj, and 1P. The circuit board 40 and each of the first and the second piece portions 31d and 31e face each other at a distance.

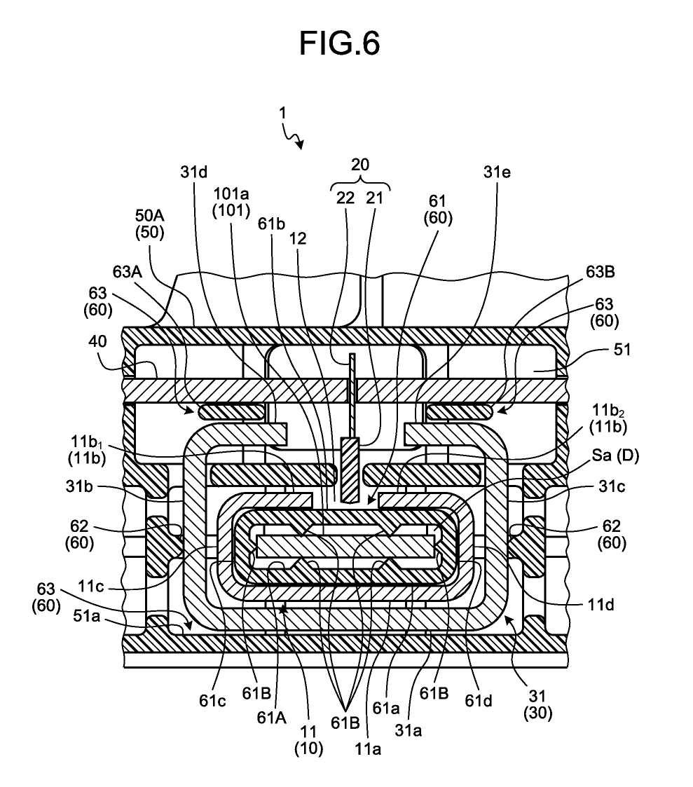

The current sensor device 5 includes a sensor housing member 50 in which the magnetic core member 10, the magnetic sensor 20, and the magnetic shield member 30 are held (FIG. 4 and FIG. 5). The sensor housing member 50 is formed of an insulating material such as a synthetic resin. This sensor housing member 50 includes a housing compartment 51 in which the magnetic core member 10, the magnetic sensor 20, and a magnetic shield member 30 are housed. The sensor housing member 50 further includes a positioning and holding mechanism 60 that enables positioning of the magnetic core member 10, the magnetic shield member 30, and the conducting member 101 in the housing compartment 51 and holds the magnetic core member 10, the magnetic shield member 30, and the conducting member 101 (FIG. 4 to FIG. 6). This sensor housing member 50 is fixed by, for example, being screwed to the inverter. FIG. 6 omits the holding body 64 to be described later.

The sensor housing member 50 may be provided to each of the current sensors 1. However, the current sensor device 5 in this example includes only one sensor housing member 50. The housing compartment 51 of the sensor housing member 50 houses the magnetic core members 10, the magnetic sensors 20, and the magnetic shield members 30 of the respective current sensors 1Um, 1Vm, 1Wm, 1Uj, 1Vj, 1Wj, and 1P. The housing compartment 51 also houses the respective conducting members 101Um, 101Vm, 101Wm, 101Uj, 101Vj, 101Wj, and 101P thereof. This sensor housing member 50 in this example has only one such housing compartment 51 formed therein that houses together the magnetic core members 10, the magnetic sensors 20, and the magnetic shield members 30 of the respective current sensors 1Um, 1Vm, 1Wm, 1Uj, 1Vj, 1Wj, and 1P. The single housing compartment 51 houses, together with the current sensors 1Um, 1Vm, 1Wm, 1Uj, 1Vj, 1Wj, and 1P, the respective conducting members 101Um, 101Vm, 101Wm, 101Uj, 101Vj, 101Wj, and 101P thereof. The sensor housing member 50 in this example also has a housing compartment 52 formed therein that houses the negative-side conducting member 102. For example, this sensor housing member 50 has the housing compartments 51 and 52 disposed side by side in the interior of a main body 50A shaped like a rectangular cylinder.

The positioning and holding mechanism 60 is provided to each of the current sensors 1Um, 1Vm, 1Wm, 1Uj, 1Vj, 1Wj, and 1P. The individual positioning and holding mechanisms 60 is formed in the housing compartment 51 integrally with the sensor housing member 50.

In this current sensor device 5, the shapes and disposition of the magnetic core members 10, the magnetic sensors 20, and the magnetic shield members 30, and the structures, shapes, and disposition of the positioning and holding mechanisms 60 of the respective current sensors 1Um, 1Vm, 1Wm, 1Uj, 1Vj, 1Wj, and 1P are substantially identical. In the current sensor device 5, identical components are used for the respective conducting members 101Um, 101Vm, 101Wm, 101Uj, 101Vj, 101Wj, and 101P. For this reason, one of the positioning and holding mechanisms 60 is described as an example representing those applied to the respective current sensors 1Um, 1Vm, 1Wm, 1Uj, 1Vj, 1Wj, and 1P.

The positioning and holding mechanism 60 includes a cylindrical housing body 61 formed in a cylindrical shape (FIG. 4 to FIG. 6). The sensor housing member 50 has the cylindrical housing body 61 provided to the housing compartment 51. The cylindrical housing body 61 has a cylinder axis in a direction along which the cylinder axis of the magnetic core member 10 extends, and is interposed between the magnetic core member 10 and the conducting member 101. This cylindrical housing body 61 is inserted through the interior of the magnetic core member 10 in a direction along the cylinder axis of the magnetic core member 10. The conducting member 101 is inserted through the interior of this cylindrical housing body 61 in a direction along the cylinder axis of the magnetic core member 10. In an AC circuit including a plurality of such conducting members 101, this cylindrical housing body 61 is provided to each of the conducting members 101.

This cylindrical housing body 61 includes: an internal circumferential wall 61A disposed facing and spaced a gap D apart from the conducting member 101 that has been inserted through the cylindrical housing body 61, the gap D being annular; and holding portions 61B protruding from a plurality of locations of the internal circumferential wall 61A toward the conducting member 101 that has been inserted through the cylindrical housing body 61, the holding portions 61B being operable to hold the conducting member 101 with the gap D maintained (FIG. 6). This cylindrical housing body 61 includes the internal circumferential wall 61A and the holding portions 61B, thus forming an air layer Sa using the gap D between itself and the conducting member 101. The air layer Sa is set in communication with the atmosphere external to the cylindrical housing body 61.

In the current sensor 1, the interposition of the air layer Sa between the cylindrical housing body 61 and the conducting member 101 enables a thermal insulation effect to be provided by the air layer Sa when the conducting member 101 generates heat by conducting electricity. That is, in this current sensor 1, the air layer Sa impedes transmission of heat generated by the conducting member 101 to the cylindrical housing body 61, which can improve the durability of the cylindrical housing body 61 and consequently improve the durability of the sensor housing member 50. In this current sensor 1, the strength of the cylindrical housing body 61 for holding the conducting member 101 therefore can be maintained, and displacement of the conducting member 101 relative to the housing compartment 51 can be prevented. Thus, the current sensor 1 in this embodiment has high thermal resistance. For this reason, the cylindrical housing body 61 is formed so that the air layer Sa can provide a thermal insulation effect.

For example, each of the holding portions 61B is preferably formed in a manner such that, in a section thereof perpendicular to the cylinder axis of the magnetic core member 10 in one side of the perpendicular section that has a contact point thereof with the conducting member 101, the section has a smaller sectional area per unit length in a direction of protrusion of the holding portion 61B in a part thereof closer to the contact point with the conducting member 101. The holding portion 61B having the above shape can contribute not only to reducing the contact area thereof with the conducting member 101 while holding the conducting member 101 but also to increasing the volume of the air layer Sa, thereby enabling the air layer Sa to have a higher thermal insulation effect.

Specifically, the cylindrical housing body 61 in this example is formed so as to be able to internally hold the conducting member 101 and enable positioning of the magnetic core member 10 in a position external from the cylindrical housing body 61. That is, the cylindrical housing body 61 in this example can be used as a position regulating unit (core-position regulating unit) that determines the relative position of the magnetic core member 10 in the housing compartment 51 and regulates that relative position from the interior of the magnetic core member 10. This cylindrical housing body 61 has an external shape agreeing with the shape (parallelepiped shape) of the internal side of the magnetic core member 10 and projects from a wall surface of the housing compartment 51 in a direction along the cylinder axis of the magnetic core member 10.

The cylindrical housing body 61 in this example is formed in a rectangular cylindrical shape having an axis identical with the cylinder axis of the magnetic core member 10. This cylindrical housing body 61 has a rectangular first wall 61a disposed facing the internal side of the first wall 11a of the core main body 11. The cylindrical housing body 61 also has a rectangular second wall 61b disposed facing the internal sides of the first piece portion 11b₁ and the second piece portion 11b₂ of the core main body 11. This cylindrical housing body 61 also has a rectangular third wall 61c disposed facing the internal side of the third wall 11c of the core main body 11. This cylindrical housing body 61 also has a rectangular fourth wall 61d disposed facing the internal side of the fourth wall 11d of the core main body 11. The distances from the cylindrical housing body 61 to the first to the fourth walls 11a to 11d are set to values that enable the cylindrical housing body 61 to be inserted through the interior of the magnetic core member 10 and also enable a positional change of the cylindrical housing body 61 relative to the magnetic core member 10 to be as small as possible. The cylindrical housing body 61 is formed in accordance with the values thus set.

The interior of the cylindrical housing body 61 in this example is a space having a parallelepiped shape. In this cylindrical housing body 61, the space having a parallelepiped shape is formed in a manner such that the internal wall surfaces of the first to the fourth walls 61a to 61d constitute the aforementioned internal circumferential wall 61A. Within the space, the current-measurement subject portion 101a of the conducting member 101 is held by the holding portions 61B.

The cylindrical housing body 61 has at least two of the holding portions 61B on each of the planar surfaces of the current-measurement subject portion 101a. In this example, two such holding portions 61B are provided on the internal circumferential wall 61A in locations belonging to each of the first wall 61a and the second wall 61b. Each of these holding portions 61B is shaped like a rib the section of which, perpendicular to a direction along the cylinder axis of the cylindrical housing body 61, is triangular. Each of the holding portions 61B on the first wall 61a and the corresponding holding portion 61B on the second wall 61b are disposed with their respective apexes facing each other in directions in which these holding portions 61B hold therebetween the respective planar surfaces of the current-measurement subject portion 101a. That is, each of these holding portions 61B is formed so as to have a smaller sectional area per unit length in a direction of protrusion of that holding portion 61B in a part thereof closer to the contact point with the corresponding planar surface of the conducting member 101.

The cylindrical housing body 61 also has at least one of the holding portions 61B on each of the end surfaces (end surfaces positioned in a direction perpendicular to the cylinder axis of the cylindrical housing body 61) of the current-measurement subject portion 101a. In this example, one such holding portion 61B is formed on the internal circumferential wall 61A in a location belonging to each of the third wall 61c and the fourth wall 61d. Each of these holding portions 61B is shaped like a rib the section of which, perpendicular to a direction along the cylinder axis of the cylindrical housing body 61, is triangular. The holding portion 61B on the third wall 61c and the holding portion 61B on the fourth wall 61d are disposed with their respective apexes facing each other in directions in which these holding portions 61B hold the respective end surfaces of the current-measurement subject portion 101a. That is, each of these holding portions 61B is formed so as to have a smaller sectional area per unit length in a direction of protrusion of that holding portion 61B in a part thereof closer to the contact point with the corresponding end surface of the conducting member 101.

The conducting member 101 is press-fit into the cylindrical housing body 61 while crushing the apexes of the respective holding portions 61B. The respective holding portions 61B of the cylindrical housing body 61 can hold the conducting member 101 in four directions toward the respective planar surfaces and end surfaces of the current-measurement subject portion 101a so that the annular gap D can be formed. As a result, the air layer Sa is formed between the cylindrical housing body 61 and the conducting member 101 in the interior of the cylindrical housing body 61.

The positioning and holding mechanism 60 further includes holding portions (hereinafter referred to as “shield holding portion”) 62 that hold the magnetic shield member 30 from the external side of the magnetic shield member 30 in order to relatively position the magnetic shield member 30 in the housing compartment 51 (FIG. 6). The shield holding portions 62 are two such portions disposed facing each other and are shaped like ribs, the two portions according to the distance between positions at which the magnetic shield member 30 is held. The shield holding portions 62 are extended from a wall surface of the housing compartment 51 in a direction along the cylinder axis of the magnetic core member 10. Sections of the respective shield holding portions 62 that are perpendicular to the cylinder axis are triangular; and the apexes of the sections are disposed facing each other in directions in which these holding portions 61B hold the magnetic shield member 30 therebetween. The magnetic shield member 30 is press-fit into the housing compartment 51 while crushing the apexes of the respective shield holding portions 62. The shield holding portions 62 in this example holds the magnetic shield member 30 therebetween in a direction in which the current sensors 1 are arranged next to each other. For this reason, in this example, one of the shield holding portions 62 is brought into abutment with the second wall 31b of the magnetic shield member 30, and the other shield holding portion 62 is brought into abutment with the third wall 31c of the magnetic shield member 30.

The positioning and holding mechanism 60 further includes position regulating portions (hereinafter referred to as “shield position regulating portions”) 63 that regulate the relative position of the magnetic shield member 30 in the housing compartment 51 in a direction intersecting the direction of the holding by the shield holding portions 62 (FIG. 6). The shield position regulating portions 63 in this example regulate the relative position of the magnetic shield member 30 in a direction perpendicular to the direction of the holding.

The shield position regulating portions 63 in this example regulate, from the external side of the magnetic shield member 30, sides of the magnetic shield member 30 that correspond to the first wall 31a and to the first and the second piece portions 31d and 31e.

In a part facing the first wall 31a, the wall surface 51a of the housing compartment 51 disposed external from the magnetic shield member 30 and facing the first wall 31a is utilized as the shield position regulating portion 63. In this example, the distance between the first wall 31a and the wall surface 51a is set to a value that can minimize relative displacement of the magnetic shield member 30 in the housing compartment 51. The position of the wall surface 51a is determined in accordance with the value thus set.

In a part facing the first and the second piece portions 31d and 31e, a first position regulating body 63A and a second position regulating body 63B that are disposed external from the magnetic shield member 30 and facing the first piece portion 31d and the second piece portion 31e, respectively, are provided as the shield position regulating portions 63. The first position regulating body 63A and the second position regulating body 63B in this example are formed as fragment pieces and protrude in a direction along the cylinder axis of the magnetic core member 10 from a wall surface of the housing compartment 51. The distance between the first position regulating body 63A and the first piece portion 31d is set to a value that can minimize relative displacement of the magnetic shield member 30 in the housing compartment 51. The first position regulating body 63A is formed in accordance with the value thus set. The distance between the second position regulating body 63B and the second piece portion 31e is set to a value that can minimize relative displacement of the magnetic shield member 30 in the housing compartment 51. The second position regulating body 63B is formed in accordance with the value thus set.

In the current sensor 1, the magnetic core member 10 and the magnetic shield member 30 are disposed in the above described positional relation in the housing compartment 51, and the magnetic sensor 20 and the circuit board 40 that are electrically connected to each other are also disposed in the housing compartment 51. The positioning and holding mechanism 60 includes a holding body 64 for maintaining the dispositions of the magnetic core members 10, the magnetic sensors 20, the magnetic shield members 30, and the circuit board 40 within the housing compartment 51 (FIG. 4). The holding body 64 in this example is an embedded body with which various gaps in the housing compartment 51 are totally filled, and is a hardened body obtained by hardening a potting agent (made of, for example, epoxy resin) with which the housing compartment 51 is filled. The holding body 64 is formed so that the air layer Sa can remain unfilled. After the members such as the magnetic core member 10 are disposed in the housing compartment 51, the holding body 64 is formed by: filling, with the potting agent, the housing compartment 51 except for the gap D in the interior of the cylindrical housing body 61; and then hardening the potting agent.

As described above, the current sensor 1 in this embodiment has improved thermal resistance due to thermal insulation effect of the air layer Sa and can consequently prevent displacement of the conducting member 101 relative to the housing compartment 51, thereby being capable of preventing changes of the sensor characteristics thereof. Therefore, this current sensor 1 can keep the detection accuracy thereof for current flowing through the conducting member 101 constant. In the current sensor device 5, the current sensors 1 thus configured are formed for the first rotating machine, for the second rotating machine, and for the positive side of the controller power supply (the current sensors 1Um, 1Vm, 1Wm, 1Uj, 1Vj, 1Wj, and 1P). Consequently, this current sensor device 5 can prevent changes of the sensor characteristics of the current sensors 1Um, 1Vm, 1Wm, 1Uj, 1Vj, 1Wj, and 1P. Therefore, this current sensor device 5 can keep the detection accuracy of the individual current sensors 1Um, 1Vm, 1Wm, 1Uj, 1Vj, 1Wj, and 1P for current flowing through the respective conducting members 101Um, 101Vm, 101Wm, 101Uj, 101Vj, 101Wj, and 101P constant.

In a current sensor according to the present embodiments, interposition of an air layer between a cylindrical housing body and a conducting member enables a thermal insulation effect to be provided by the air layer when the conducting member generates heat by conducting electricity. That is, in this current sensor, the air layer impedes transmission of heat generated by the conducting member to the cylindrical housing body, which can improve the durability of the cylindrical housing body and consequently improve the durability of the sensor housing member. In this current sensor, the strength of the cylindrical housing body for holding the conducting member therefore can be maintained, and the conducting member can be prevented from being displaced relative to the housing compartment. Thus, the current sensor according to the present embodiments has excellent thermal resistance.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A current sensor comprising:
a magnetic core member including a core main body formed of a cylindrical body that internally surrounds, at a distance, a conducting member through which electricity is passed, the cylindrical body having a gap portion formed therein that is formed as a slit extending in a direction along a cylinder axis of the cylindrical body, the magnetic core member being configured to generate magnetic flux corresponding to current flowing through the conducting member;
a magnetic sensor configured to output a signal corresponding to a magnetic flux density of the gap portion;
a magnetic shield member including a shield main body that surrounds external sides of the core main body, the shield main body being operable to shield magnetism between an interior and an exterior of the shield main body; and
a sensor housing member configured to internally house the magnetic core member, the magnetic sensor, and the magnetic shield member, wherein
the sensor housing member includes a cylindrical housing body shaped as a cylinder and operable to be inserted through the interior of the magnetic core member in a direction along the cylinder axis and have the conducting member inserted through the interior of the cylindrical housing body itself in the direction along the cylinder axis,
the cylindrical housing body includes
an internal circumferential wall disposed facing and spaced a gap apart from the conducting member that has been inserted through the cylindrical housing body, the gap being annular, and
a plurality of holding portions protruding from a plurality of respective locations of the internal circumferential wall toward the conducting member that has been inserted through the cylindrical housing body, the holding portions being operable to hold the conducting member with the gap being maintained, and
the cylindrical housing body forms an air layer using the gap between the cylindrical housing body and the conducting member that has been inserted through the interior thereof.

2. The current sensor according to claim 1, wherein
each of the holding portions is formed in a manner such that, in a section thereof perpendicular to the cylinder axis, and in a contact point side thereof with the conducting member in the perpendicular section, the cross-section area per unit length in a direction of protrusion of the holding portion decreases toward the contact point with the conducting member.

3. The current sensor according to claim 1, wherein
in an alternating-current circuit that includes a plurality of the conducting members, combinations each composed of the magnetic core member, the magnetic sensor, and the magnetic shield member are provided to the respective conducting members, and
the individual cylindrical housing body is provided to each of the conducting members in the alternating-current circuit.

4. The current sensor according to claim 2, wherein
in an alternating-current circuit that includes a plurality of the conducting members, combinations each composed of the magnetic core member, the magnetic sensor, and the magnetic shield member are provided to the respective conducting members, and
the individual cylindrical housing body is provided to each of the conducting members in the alternating-current circuit.
